(19) United States
(12) Patent Application Publication
(10) Pub. No.: US 2025/0142946 A1
(43) Pub. Date: May 1, 2025

(54) BACKSIDE ISOLATION OF SEMICONDUCTOR STRUCTURES

(71) Applicant: Taiwan Semiconductor Manufacturing Company, Ltd., Hsinchu (TW)

(72) Inventors: Jui-Lin Chen, Taipei (TW); Gu-Huan Li, Hsinchu (TW); Ping-Wei Wang, Hsinchu (TW); Lien-Jung Hung, Taipei (TW); Chen-Ming Lee, Taoyuan (TW)

(73) Assignee: Taiwan Semiconductor Manufacturing Company, Ltd., Hsinchu (TW)

(21) Appl. No.: 18/494,253

(22) Filed: Oct. 25, 2023

(51) Int. Cl. H01L 27/088; H01L 21/8234; H01L 23/528; H01L 29/06; H01L 29/417; H01L 29/423; H01L 29/775; H01L 29/786

(52) U.S. Cl. CPC H10D 84/83; H01L 23/5286; H10D 30/43; H10D 30/6735; H10D 30/6757; H10D 62/121; H10D 64/254; H10D 84/0151; H10D 84/038

(57) ABSTRACT

Semiconductor structures and methods for fabricating semiconductor structures are provided. A semiconductor structure includes a first fin extending in an X-direction and a second fin parallel to the first fin and distanced from the first fin in a Y-direction perpendicular to the X-direction. Each fin is formed with a first device area and a second device area aligned in the X-direction; an isolation region disposed between the fins; an isolation structure disposed between the device areas in each fin; and an isolation layer disposed under the fins. The isolation region contacts the isolation layer, the isolation structure contacts the isolation layer, and the isolation region contacts the isolation structure to isolate the first fin from the second fin and to isolate the first device area from the second device area in each fin.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far the demand has been met in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Multi-gate devices have been introduced in an effort to improve gate control by increasing gate-channel coupling, reducing OFF-state current, and reducing short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA devices get their name from the gate structure which extends completely around the channel, providing better electrostatic control than FinFETs. FinFET devices and GAA devices are compatible with conventional complementary metal-oxide-semiconductor (CMOS) processes. Further, the three-dimensional structure of such devices allows them to be aggressively scaled while maintaining gate control and mitigating SCEs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic bottom view of a semiconductor structure in accordance with some embodiments.

FIG. 2 is a schematic X-cut cross-section view of the semiconductor structure of FIG. 1 in accordance with some embodiments.

FIG. 3 is a schematic X-cut cross-section view of the semiconductor structure of FIG. 1 in accordance with other embodiments.

FIG. 4 is a schematic X-cut cross-section view of the semiconductor structure of FIG. 1 in accordance with other embodiments.

FIG. 5 is a schematic X-cut cross-section view of the semiconductor structure of FIG. 1 in accordance with some embodiments.

FIGS. 6-21 are schematics illustrating a method for fabricating a semiconductor structure in accordance with some embodiments, wherein FIGS. 6-10, 12, 14, 16, 18, and 20 are perspective views, and FIGS. 11, 13, 15, 17, 19, and 21 are Y-cut cross section views of the preceding respective perspective views.

FIGS. 22-24 are schematic X-cut cross-section views of a semiconductor structure during successive fabrication stages in accordance with some embodiments.

FIGS. 25-26 are schematic X-cut cross-section views of a semiconductor structure during successive fabrication stages in accordance with some embodiments.

FIGS. 27-28 are schematic Y-cut cross-section views of a semiconductor structure during successive fabrication stages in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “frontside”, “backside”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

In certain embodiments herein, a “material layer” is a layer that includes at least 50 wt. % of the identified material, for example at least 60 wt. % of the identified material, or at least 75 wt. % of the identified material, or at least 90 wt. % of the identified material; and a layer that is a “material” includes at least 50 wt. % of the identified material, for example at least 60 wt. % of the identified material, at least 75 wt. % of the identified material, or at least 90 wt. % of the identified material. For example, certain embodiments, each of a titanium nitride layer and a layer that is titanium nitride is a layer that is at least 50 wt. %, at least 60 wt. %, at least 75 wt. %, titanium nitride, or at least 90 wt. % titanium nitride.

For the sake of brevity, common techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Embodiments herein provide for forming semiconductor devices, such as gate-all-around (GAA) field effect transistors (FETs), on a device frontside. Further, embodiments herein provide for forming a backside interconnect structure, which may sometimes be referred to as a super power rail (SPR) or backside power rail (BPR), for powering the semiconductor devices. Moreover, embodiments herein provide for isolation of the semiconductor devices and/or super power rail (SPR). As a result, junction leakage that may cause data retention or disturb is reduced or eliminated. Specifically, high voltage (HV) coupling from source/drain features to substrate and stress to unselected devices is reduced or eliminated. Further, well isolation designs may be obviated through approaches described herein.

In certain embodiments, mesa portions of the semiconductor substrate under adjacent device areas are physically separated and electrically isolated from each other by an isolation structure in the form of a backside via surrounded by an isolation material. In certain embodiments, mesa portions of the semiconductor substrate under adjacent device areas are physically separated and electrically isolated from each other by an isolation structure in the form of a Continuous Poly On Diffusion Edge (CPODE) structure. In certain embodiments, adjacent fins are isolated from each other by thinning down the semiconductor substrate or wafer to remove the semiconductor material interconnecting the fins under the shallow isolation. As a result, in each embodiment, time-dependent dielectric breakdown (TDDB) may be improved, junction leakage may be reduced, and stress may be reduced. Further, by thinning the backside semiconductor material, well leakage noise is reduced, and the need for an N-doped deep well may be eliminated.

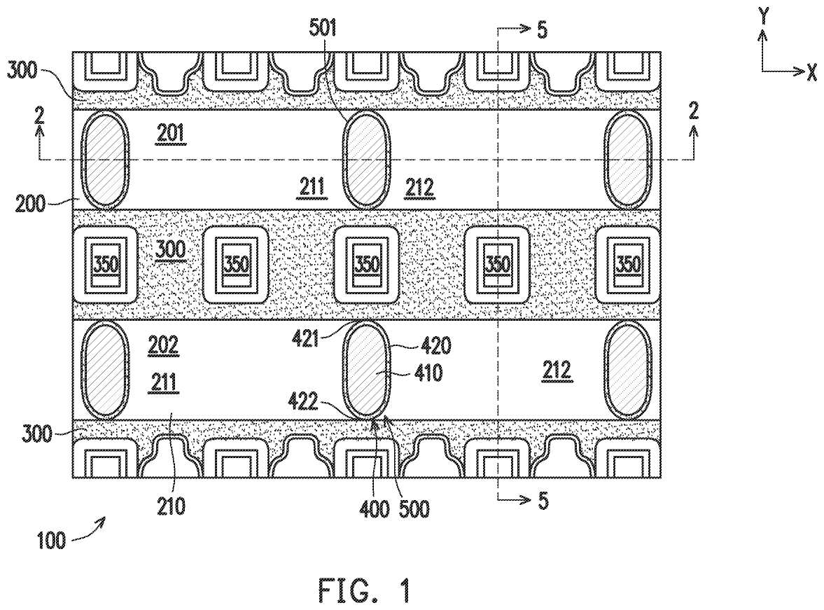

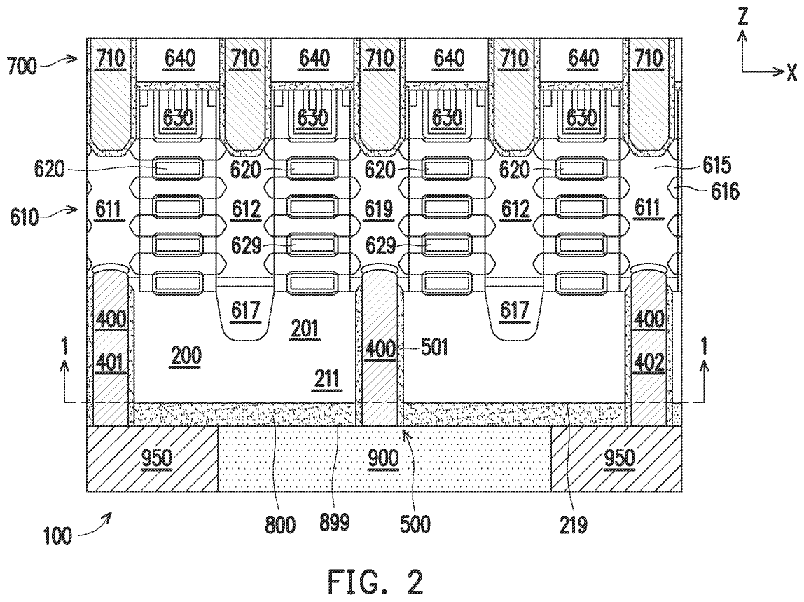

Referring to FIG. 1, a schematic bottom view (or Z-cut cross-section view) of a semiconductor structure 100 in accordance with some embodiments is provided. FIG. 2 is a schematic X-cut cross-section view of the semiconductor structure of FIG. 1. Specifically, the cross-section view of FIG. 2 is taken along line 2-2 in FIG. 1. Likewise, the cross-section view of FIG. 1 is taken along line 1-1 in FIG. 2.

As shown in FIG. 1, the semiconductor structure 100 includes fins 200, including a first fin 201 and a second fin 202 that are parallel and extend in the X-direction. As shown, the fins 201 and 202 are distanced from one another in the Y-direction.

Each fin 200 includes a plurality of device areas 210 or semiconductor substrate portions 210. For example, each fin 200 includes a first device area 211 and a second device area 212. Device areas 211 and 212 are laterally adjacent one another, i.e., in the X-direction.

As shown in FIG. 1, the semiconductor structure 100 includes isolation regions 300, such as shallow trench isolation (STI) regions 300, that are parallel and extend in the X-direction. As shown, the isolation regions 300 are distanced from one another in the Y-direction. Each isolation region 300 is located between a pair of adjacent fins 200.

Further, interlayer dielectric (ILD) regions 350 may be disposed within the isolation regions 300 and may extend vertically (in the Z-direction).

As shown in FIG. 1, the semiconductor structure 100 includes backside vias 400 that are disposed within the fins 200 and that extend vertically (in the Z-direction). The backside vias 400 include a conductive core 410. For example, the conductive core 410 may be formed from tungsten or another suitable conductive metal material. Further, the backside vias 400 include a dielectric layer 420 that surrounds the conductive core 410. At the height or level of FIG. 1, the dielectric layer 420 is annular or ring-shaped. In certain embodiments, the dielectric layer 420 is silicon nitride, or another dielectric material suitable for insulation.

As shown, each dielectric layer 420 longitudinally extends (in the Y-direction) completely across the fins 200 from a first end 421 to a second end 422, such that the first end 421 contacts an isolation region 300 and the second end 422 contacts an isolation region 300. As a result, each dielectric layer 420 acts as an isolation structure 500 physically separating and electrically isolating adjacent device areas 210 within each fin 200.

Specifically, in FIG. 1, a selected isolation structure 501 is located between the first device area 211 and the second device area 212 in the first fin 201. The isolation structure 501, comprising a dielectric layer 420, physically separates the first device area 211 from the second device area 212 in the first fin 201. Further, the isolation structure 501, comprising a dielectric layer 420, electrically isolates the first device area 211 from the second device area 212 in the first fin 201.

Referring now to FIG. 2, further features of the semiconductor structure 100 are illustrated. As shown, in each device area 211 and 212, the semiconductor structure 100 includes source/drain features 610, such as a source feature 611 and a drain feature 612, over the respective fin 201. As used herein, “source/drain feature(s)” may refer to a source feature or a drain feature, individually or collectively depending on the context.

As further shown, in each device area 211 and 212, the semiconductor structure 100 includes an active region 620 between the source/drain features 610. In the illustrated embodiment, the active region 620 is formed by nanosheets in the embodiment of a GAA FET.

Further, in each device area 211 and 212, the semiconductor structure 100 includes a gate structure 630 over the active region 620. For example, the gate structure 630 may include a high K dielectric and metal gate electrode. An interlayer dielectric material 640 may be formed over the gate structures 630.

In FIG. 2, the semiconductor structure 100 includes a frontside interconnect structure 700 disposed over the source/drain features 610 and the gate structures 630 of each device area 211 and 212. For example, the frontside interconnect structure 700 may include conductive contacts 710 connected to selected source/drain features 610.

In certain embodiments, each source/drain feature 610 may be formed form highly doped material 615, i.e., epitaxial material having a high dopant concentration, and from lightly doped material 616, i.e., epitaxial material having a lower dopant concentration. As shown, each source/drain feature 610 may include a bottom structure 617. In some embodiments, the bottom structure 617 is un-doped material, e.g., undoped silicon. In other embodiments, the bottom structure 617 is a flexible bottom insulator (FBI), instead of un-doped silicon. In some embodiments, the bottom structure 617 may include un-doped material, e.g., undoped silicon, and a flexible bottom insulator (FBI).

As shown in FIG. 2, the semiconductor material of the mesa portions or device areas 210 of the fins 200 extends vertically downward, in the Z-direction, and terminates at a backside 219. In some embodiments, the backside 219 is planar. Further, the semiconductor structure 100 includes an inner isolation layer 800 disposed below the backside 219. In certain embodiments, the inner isolation layer 800 is disposed directly on the backside 219. The inner isolation layer 800 may be silicon nitride, or another dielectric material suitable for insulation.

As shown in FIG. 2, backside vias 400 extend from contact with selected source/drain features 610, through the semiconductor material of the mesa portions or device areas 210 of the fins 200, and past the backside 219 of the semiconductor material of the fins 200. In certain embodiments, the backside vias 400 extend through the inner isolation layer 800 to a shared bottom surface 899 defined by the inner isolation layer 800 and by the backside vias 400. In some embodiments, the shared bottom surface 899 is planar.

Thus, the dielectric layer 420 of the backside vias 400, defining the isolation structure 500, directly contacts the inner isolation layer 800. As a result, the conductive core 410 of the backside via 400 is completely physically separated from and electrically isolated from the semiconductor material of the mesa portions or device areas 210 of the fins 200.

As further shown in FIG. 2, the semiconductor structure 100 includes an outer isolation layer 900 located below the selected isolation structure 501. Specifically, the outer isolation layer 900 is disposed directly on the shared bottom surface 899 at the selected isolation structure 501 and the inner isolation layer 800 adjacent to the selected isolation structure 501. As a result, the dielectric layer 420 of the backside vias 400, defining the isolation structure 500, directly contacts the outer isolation layer 900. As a result, the conductive core 410 of the backside via 400 forming the selected isolation structure 501 is electrically disconnected from any conductive path.

In FIG. 2, the semiconductor structure 100 includes a backside interconnect structure 950 disposed under the fin 200 and laterally adjacent, in the X-direction, to the outer isolation layer 900. In some embodiments, the backside interconnect structure 950 is formed by a metal layer, such as by a copper or aluminum layer, or by another suitable conductive material. In FIG. 2, the backside interconnect structure 950 is disposed under, and directly on, the inner isolation layer 800.

As shown in FIG. 2, active backside vias 401 and 402 contact and are in electrical connection with the backside interconnect structure 950. In the embodiment of FIG. 2, active backside vias 401 and 402 are in contact with the source feature 611 in each device area 211 and 212.

Cross-referencing FIGS. 1 and 2, a semiconductor structure 100 includes a first device area 211 and a second device area 212 adjacent to the first device area 211, wherein each device area includes a semiconductor substrate or fin 201, a source feature 611 and a drain feature 612 over the semiconductor substrate 201; an active region 620 between the source feature 611 and the drain feature 612; and a gate structure 630 over the active region 620; an isolation structure 501 disposed between the semiconductor substrate 201 in the first device area 211 and the semiconductor substrate 201 in the second device area 212; wherein each semiconductor substrate 201 terminates at a backside 219, and wherein the isolation structure 501 extends to the backside 219.

As described, the isolation structure 501 is a dummy backside via 400 including a conductive core 410 surrounded by a dielectric layer 420. As a dummy backside via 400, the conductive core 410 extends downward to a dead end that is not electrically connected to any conductive feature.

The semiconductor structure 100 further includes an isolation layer, such as outer isolation layer 900, that is disposed under the backside 219 of each semiconductor substrate 201, and the isolation structure 501 contacts the isolation layer 900.

The semiconductor structure 100 further includes an active backside via 401 in contact with the source feature 611 in the first device area 211, and an active backside via 402 in contact with the source feature 611 in the second device area 212. Also, the semiconductor structure 100 includes a backside interconnect structure 950 disposed under the backside 219 of the semiconductor substrate 201 in the first device area 211 and adjacent to the isolation layer 900, wherein the active backside via 401 contacts the backside interconnect structure 950.

As further shown, among the active regions 620, each device area 211 and 212 includes a terminal active region 629 adjacent to the other device area 212 or 211. The semiconductor structure 100 further includes, among the source/drain features 610, a dummy source/drain feature 619 disposed between the terminal active regions 629. As shown, the isolation structure 501 contacts the dummy source/drain feature 619.

In FIGS. 1-2, the semiconductor structure 100 includes a frontside interconnect structure 700 disposed over the source feature 611, the drain feature 612, and the gate structure 630 of each device area 211 and 212.

With the design of the semiconductor structure of FIG. 2, the backside via isolation structure 500 separates the active areas, such that there is no stress impact to unselected devices. For example, high voltage couple from source/drain features to the substrate is reduced or eliminated to avoid stress to the unselected device.

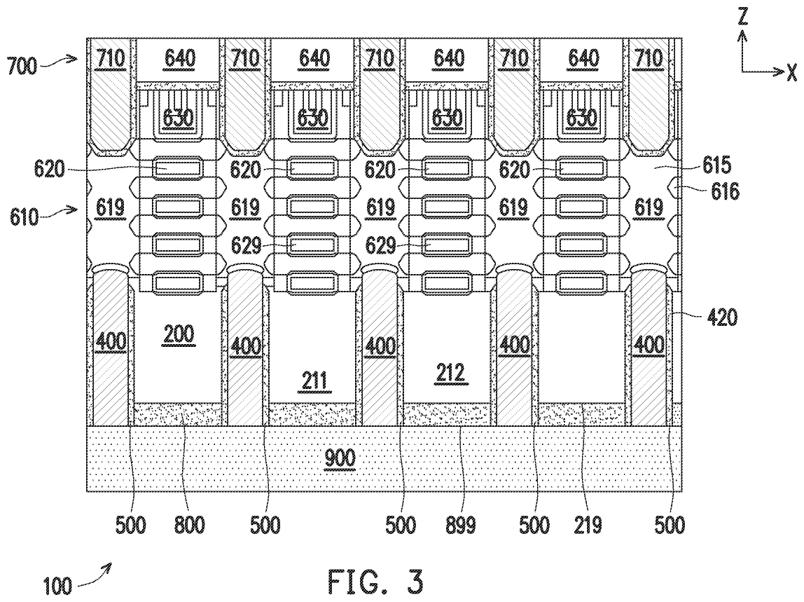

Referring now to FIG. 3, an alternative embodiment of the semiconductor structure 100 is provided. FIG. 3 is a similar view to FIG. 2, i.e., a schematic X-cut cross-section view of the semiconductor structure of FIG. 1, such as taken along line 2-2 in FIG. 1.

Unlike the embodiment of FIG. 2, in FIG. 3 the semiconductor structure 100 is formed with no backside vias 400 that electrically connect to a backside interconnect structure. Rather, the outer isolation layer 900 continuously contacts the shared bottom surface 899 defined by the inner isolation layer 800 and by the backside vias 400 across device areas 211 and 212. Therefore, the dielectric layer 420 of each backside via 400 forms an isolation structure 500. Accordingly, each source/drain feature 610 is formed as a dummy source/drain feature 619.

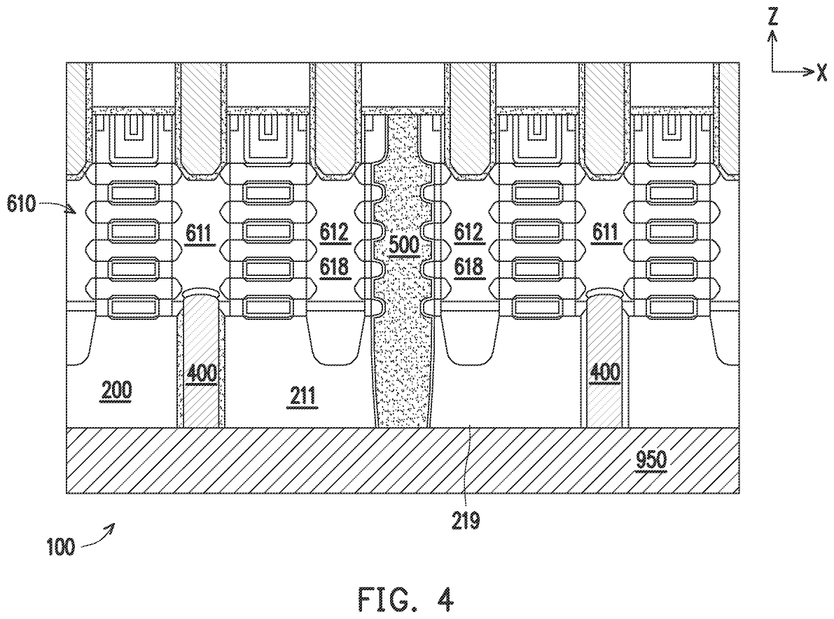

FIG. 4 illustrates another embodiment of a semiconductor structure 100. In FIG. 4, the isolation structure 500 is formed by a continuous poly on diffusion edge (CPODE) process. Thus, the isolation structure 500 is a Continuous Poly On Diffusion Edge (CPODE) structure. Similar to the embodiment of FIG. 2, the isolation structure 500 in FIG. 4 physically separates and electrically isolates the first mesa portion or device area 211 of the fin from the second mesa portion or device area 212 of the fin.

As shown in FIG. 4, the semiconductor structure 100 includes a semiconductor substrate or fin with a first device area 211 and a second device area 212, source/drain features including source features 611 and drain features 612, active regions, gate structures, and a frontside interconnect structure as described above.

Unlike the embodiment of FIGS. 2 and 3, the semiconductor structure 100 may not include an inner isolation layer 800 and/or outer isolation layer 900. Because the CPODE isolation structure 500 does not include a conductive core, the CPODE isolation structure 500 is not required to be grounded or dead ended into an isolation material.

As shown in FIG. 4, the fin or semiconductor substrate 200 terminates at backside 219 and the CPODE isolation structure 500 extends to, and terminates at, the backside 219. In FIG. 4, the active backside vias 400 physically contact the backside interconnect structure 950 at the backside 219.

In the embodiment of FIG. 4, each device area 211 and 212 includes a terminal source/drain feature 618 from among the source/drain features 610. As shown, the CPODE isolation structure 500 is disposed directly adjacent to and between the terminal source/drain features 618.

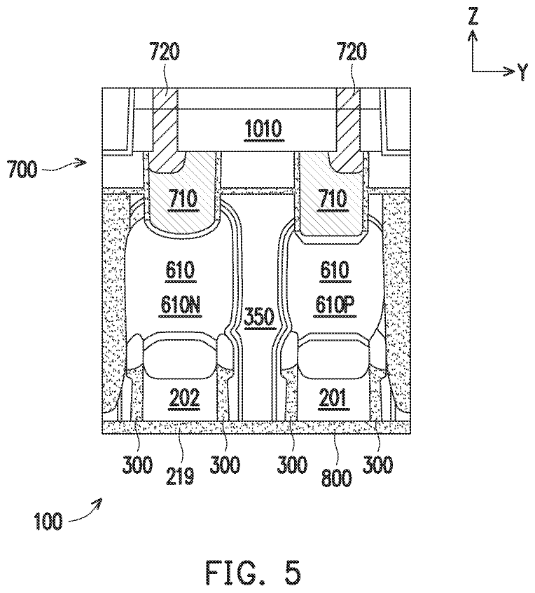

FIG. 5 provides a Y-cut cross-sectional view, such as along line 5-5 in FIG. 1 to illustrate features of the semiconductor structure 100 not shown in the X-cut views of FIGS. 2-4.

In FIG. 5, fin 201 and fin 202 are spaced from one another in the Y-direction. As shown, an interlayer dielectric (ILD) region 350 is disposed between the fins 201 and 202 and extends vertically (in the Z-direction). Further, portions of the shallow trench isolation (STI) regions 300 are longitudinally adjacent (in the Y-direction) to each fin 201 and 202. For example, the STI regions 300 are located between the ILD region 350 and the fins 201 and 202.

The fins 201 and 202, ILD region 350, and STI regions 300 all extends downward (in the Z-direction) and terminate at the backside 219. In some embodiments, the backside 219 is planar. As shown, the inner isolation layer 800 is located below, and directly on, the backside 219. In the illustrated embodiment, the inner isolation layer 800 forms a continuous, non-interrupted, interface with the backside 219.

As shown, source/drain features 610 are located over the fins 201 and 202. In some embodiments, the source/drain features 610 over adjacent fins 201 and 202 are differently doped. For example, the source/drain feature 610 over fin 201 may be P-doped epitaxial material 610P and the source/drain feature 610 over fin 202 may be N-doped epitaxial material 610N.

As further shown, the frontside interconnect structure 700 is formed over the source/drain features 610 and includes conductive contacts 710 connected to the source/drain features 610. Further, an additional interlayer dielectric (ILD) region 1010 may be located over the conductive contacts 710 and the frontside interconnect structure 700 may include conductive interconnects 720 that extend through the ILD region 1010 to interconnect with conductive contacts 710 as shown.

Thus, FIGS. 1 and 5 illustrate that the semiconductor structure 100 includes a first fin extending 201 in the X-direction and a second fin 202 parallel to the first fin 201 and distanced from the first fin 201 in the Y-direction perpendicular to the X-direction. Further, the semiconductor structure 100 includes an isolation region 300 disposed between the first fin 201 and the second fin 202. Also, the semiconductor structure 100 includes an isolation layer 800 disposed under the first fin 201 and the second fin 202, wherein the isolation region 300 contacts the isolation layer 800, and the isolation region 300 contacts the isolation structure 500 to isolate the first fin 201 from the second fin 202.

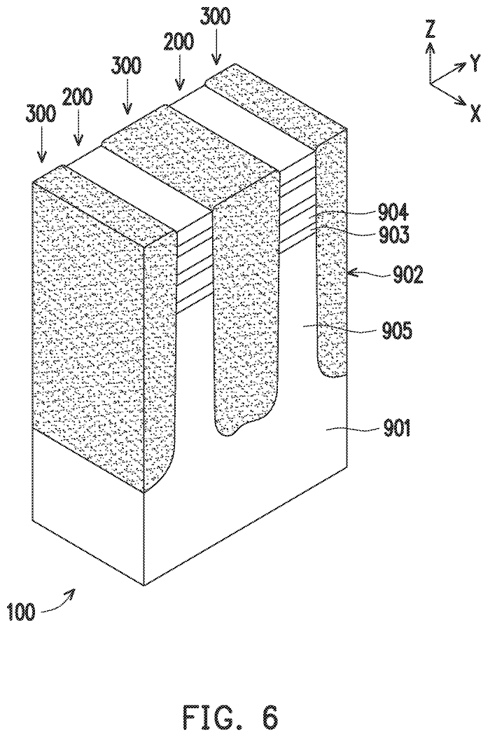

FIGS. 6-21 illustrate a method for fabricating a semiconductor structure 100 of an embodiment or embodiments illustrated in FIGS. 1-5.

In FIG. 6, the method includes providing a substrate 901. In some embodiments, the substrate 901 includes a single crystalline semiconductor layer on at least it surface portion. The substrate 901 may comprise a single crystalline semiconductor material such as, but not limited to Si, Ge, SiGe, GaAs, InSb, GaP, GaSb, InAlAs, InGaAs, GaSbP, GaAsSb and InP. In certain embodiments, the substrate 901 is made of crystalline Si.

As shown in FIG. 6, the method forms one or more epitaxial layers over the substrate 901. In some embodiments, an epitaxial stack 902 is formed over the substrate 901. The epitaxial stack 902 includes epitaxial layers 903 of a first composition interposed by epitaxial layers 904 of a second composition. The first and second composition may be different. Embodiments are possible including those that provide for a first composition and a second composition having different oxidation rates and/or etch selectivity. In an embodiment, the epitaxial layers 903 are SiGe and the epitaxial layers 904 are silicon. In embodiments wherein the epitaxial layer 903 includes SiGe and the epitaxial layer 904 includes silicon, the silicon oxidation rate is less than the SiGe oxidation rate. It is noted that three layers of epitaxial layers 903 and three layers of epitaxial layers 904 are illustrated in FIG. 6, which is for illustrative purposes only and not intended to be limiting beyond what is specifically recited in the claims. It can be appreciated that any number of epitaxial layers may be formed in the epitaxial stack 902; the number of layers depending on the desired number of channels regions for the GAA device in the semiconductor structure 100. In some embodiments, the number of epitaxial layers 904 is between two and ten.

As shown in FIG. 6, the method patterns the epitaxial stack 902 to form semiconductor fins 200. While FIG. 6 illustrates the formation of two fins 200, any suitable number of the fins may be formed. Trenches are etched between adjacent fins 200.

In various embodiments, each fin 200 includes an upper portion of the interleaved epitaxial layers 903 and 904, and a bottom or mesa portion 905 that is formed from the etched substrate 901. Each fin 200 protrudes upwardly in the Z-direction from the substrate 901 and extends lengthwise in the X-direction. Fins 200 are spaced apart along the Y-direction. Sidewalls of each fin 200 may be straight or inclined. At the stage of fabrication of FIG. 6, the fins 200 remain interconnected by the semiconductor material of the unetched substrate 901.

As shown in FIG. 6, the method forms shallow trench isolation (STI) features (also denoted as STI features) 300 in trenches adjacent to each fin 200 with a dielectric layer. The STI regions 300 may be formed by first filling the trenches around each fin 200 with a dielectric material layer to cover top surfaces and sidewalls of the fin 200 (not shown). The dielectric material layer may include one or more dielectric materials. Suitable dielectric materials for the dielectric layer may include silicon oxides, silicon nitrides, silicon carbides, fluorosilicate glass (FSG), low-K dielectric materials, and/or other suitable dielectric materials. The dielectric material may be deposited by any suitable technique including thermal growth, flowable CVD (FCVD), HDP-CVD, PVD, ALD, and/or spin-on techniques. The dielectric material layer is then planarized by using, for example, chemical mechanical planarization (CMP). The dielectric material layer may then be recessed to form the STI regions 300. In the illustrated embodiment, the STI regions 300 are formed on the substrate 901. Any suitable etching technique may be used to recess the isolation regions 300 including dry etching, wet etching, RIE, and/or other etching methods, and in an exemplary embodiment, an anisotropic dry etching is used to selectively remove the dielectric material of the isolation regions 300 without etching the fins 200.

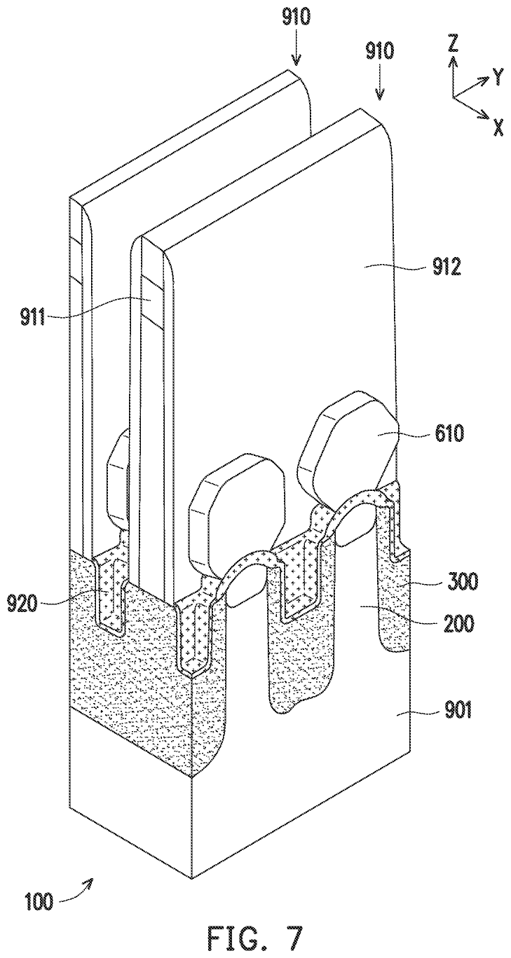

As shown in FIG. 7, the method may form sacrificial (dummy) gate structures 910. The sacrificial gate structures 910 are formed over portions of the fin 200 which are to be channel regions. The sacrificial gate structures 910 may extend over a number of adjacent fins. The sacrificial gate structures 910 lie directly over and define the channel regions of the GAA devices to be formed. Each of the sacrificial gate structures 910 includes a sacrificial gate dielectric and a sacrificial gate electrode over the sacrificial gate dielectric. As shown, the gate structures 910 extend lengthwise in the Y-direction and are spaced apart in the X-direction.

The sacrificial gate structures 910 may be formed by first blanket depositing a sacrificial gate dielectric layer over the fins 200. A sacrificial gate electrode layer is then blanket deposited on the sacrificial gate dielectric layer and over the fins 200. The sacrificial gate dielectric layer includes silicon oxide, silicon nitride, or a combination thereof. The sacrificial gate electrode layer may include silicon, such as polycrystalline silicon or amorphous silicon. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. A mask layer 911 is formed over the sacrificial gate electrode layer. The mask layer 911 may include a mask sublayer such as silicon oxide and a mask sublayer such as silicon nitride. Subsequently, a patterning operation is performed on the mask layer 911, the sacrificial gate electrode layers and the sacrificial gate dielectric layer are patterned into the sacrificial gate structures 910.

The fin 200 is partially exposed between and on opposite sides of the sacrificial gate structures 910, thereby defining source/drain (S/D) regions. In this disclosure, a source and a drain are interchangeably used and the structures thereof are substantially the same.

Still referring to FIG. 7, the method forms spacers 912 on sidewalls of the sacrificial gate structures 910 and sidewalls of the fins 200 by depositing spacer materials, followed by an etching. The spacers 912 may include spacer material such as silicon oxide, silicon nitride, silicon carbide, silicon oxynitride, SiCN films, silicon oxycarbide, SiOCN films, and/or combinations thereof. In some embodiments, each of the spacers 912 include multiple layers, such as a liner layer and a main spacer layer on a sidewall of the liner layer.

By way of example, the spacers 912 may be formed by depositing spacer material including a liner material layer and a dielectric material layer over the sacrificial gate structure 910 using processes such as a subatmospheric CVD (SACVD) process, a flowable CVD process, an ALD process, a PVD process, or other suitable process respectively.

As shown in FIG. 7, the deposition of the liner material layer and the dielectric material layer are followed by etching-back (e.g., anisotropically) to expose, and remove, portions of the fins 200 adjacent to and not covered by the sacrificial gate structure 910 (e.g., S/D regions). The liner material layer and the dielectric material layer may remain on the sidewalls of the sacrificial gate structure 910 as the gate sidewall spacers 912, and on the sidewalls of the fins as the fin sidewall spacers 912. In some embodiments, the etching-back process may include a wet etch process, a dry etch process, a multiple-step etch process, and/or a combination thereof.

The method may continue with forming an isolation layer 920 over the semiconductor substrate 901. Specifically, the isolation layer 920 is formed on the bottom surfaces of the gaps created by etching back the S/D regions of the fins 200. In exemplary embodiments, the isolation layer 920 is formed by an atomic layer deposition (ALD) process. In exemplary embodiments, the isolation layer 920 is a dielectric material with a large band gap. In certain embodiments, the isolation layer 920 is formed from silicon oxide, silicon nitride, or a combination thereof.

As shown in FIG. 7, the method may continue with forming source/drain features 610 in the S/D regions. In exemplary embodiments, the source/drain features 610 are formed by epitaxial growth. The epitaxial material may include one or more layers of Si, SiP, SiC and SiCP for an n-channel FET or Si, SiGe, Ge for a p-channel FET. For the P-channel FET, boron (B) may also be contained in the source/drain. The source/drain epitaxial layers may be formed by an epitaxial growth method using CVD, ALD, or molecular beam epitaxy (MBE).

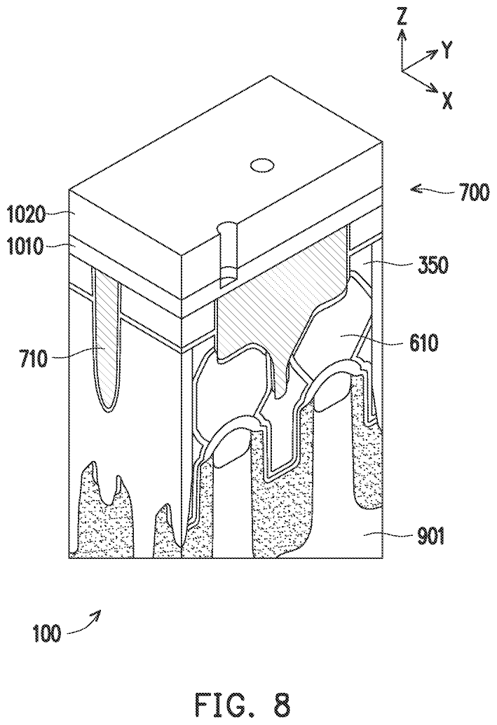

Referring to FIG. 8, the method may continue with forming interlayer dielectric (ILD) region 350 over the source/drain features 610.

Further, the method may include opening the sacrificial gate structures 910. Specifically, a chemical mechanical planarization (CMP) process may be performed to uncover the sacrificial gate electrode. Then, the method may remove the sacrificial gate electrode to form gate cavities bounded by the sidewall spacers 912. The method may then remove the epitaxial layers 903 to define the epitaxial layers 904 as vertically-spaced apart semiconductor nanosheets. The method then completes a replacement metal gate process to form gate structures. After completing the replacement metal gate process, method may continue with forming a cut metal gate isolation structure to isolate adjacent devices.

As shown in FIG. 8, the method may then form conductive contacts 710 and an interlayer dielectric region 1010 over the semiconductor structure 100. Further processing may include patterning a mask 1020 over the ILD region 1010, etching the ILD region 1010, and forming conductive interconnects 720 that extend through the ILD region 1010 to interconnect with conductive contacts 710.

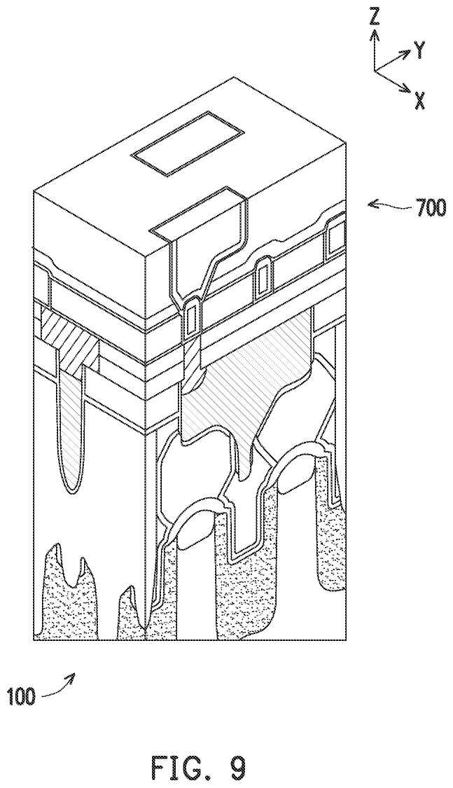

As shown in FIG. 9, Back-End-of-Line (BEOL) is then performed to complete the frontside interconnect structure 700.

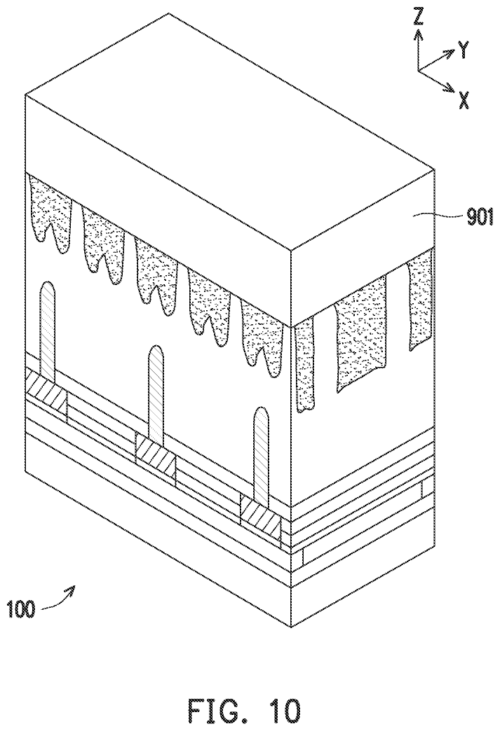

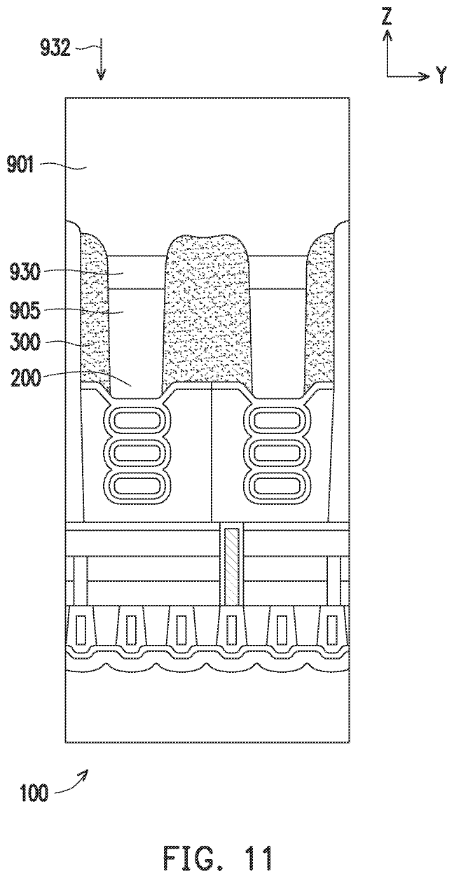

In FIG. 10, the semiconductor structure 100 is flipped, and backside processing is performed. FIG. 11 is a cross-sectional view of the semiconductor structure 100 of FIG. 10.

As shown in FIGS. 10 and 11, the unetched portion of the semiconductor substrate 901 remains connecting the mesa portions 905 of the fins 200. In some embodiments, the semiconductor substrate 901 may include an etch stop layer 930 as shown. The etch stop layer extends laterally between STI regions 300.

In FIGS. 10 and 11, a dry thin down process is performed to remove a backside portion of the semiconductor substrate 901, such as in the direction of arrow 932.

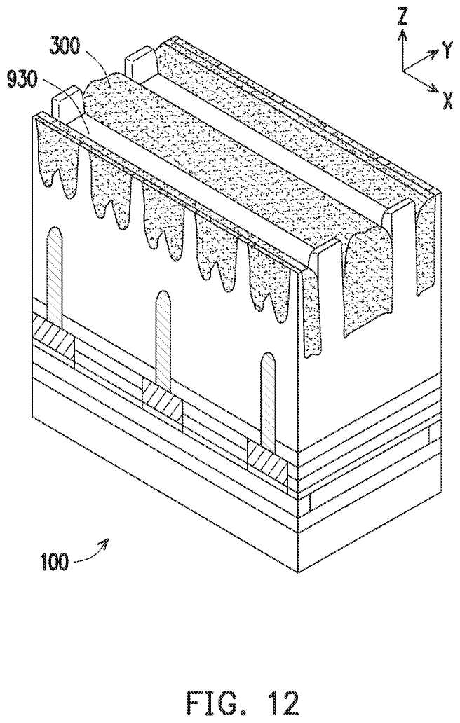

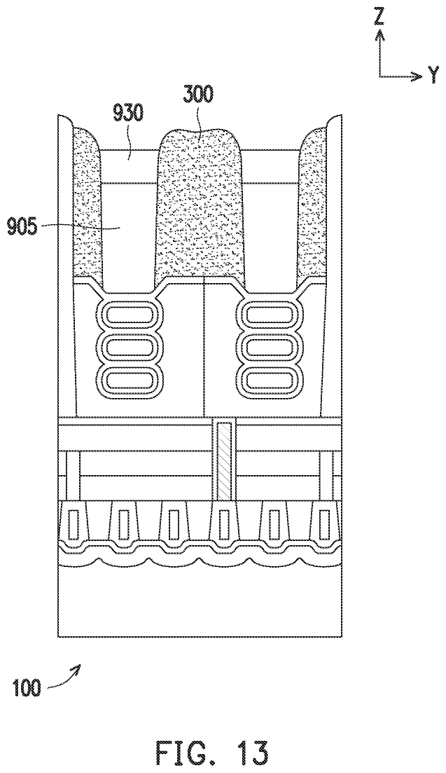

In FIG. 12, the method continues with a wet removal of the remaining portion of the semiconductor substrate 901 located above the etch stop layer 930 in the flipped orientation of FIGS. 10-12. FIG. 13 is a cross-sectional view of the semiconductor structure 100 of FIG. 12.

As a result of the wet removal of the semiconductor substrate 901, the etch stop layer 930 and STI regions 300 are uncovered.

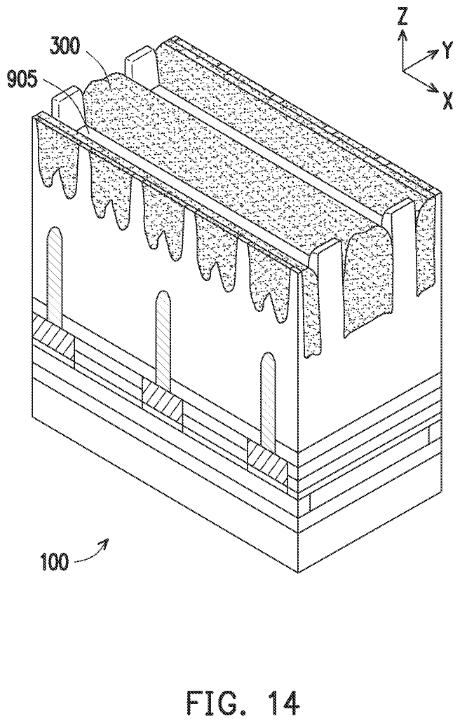

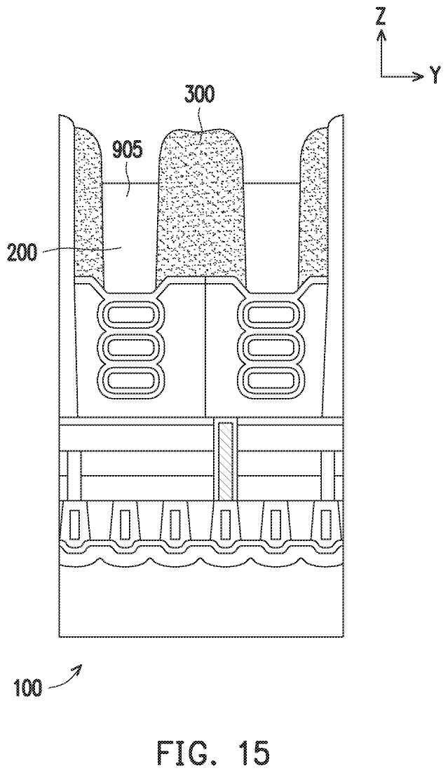

In FIG. 14, the method continues with a wet removal of the etch stop layer 930. FIG. 15 is a cross-sectional view of the semiconductor structure 100 of FIG. 14.

As a result of the removal processes of FIGS. 12-15, the mesa portions 905 of the fins 200 are physically disconnected, i.e., no semiconductor material remains interconnecting the fins 200.

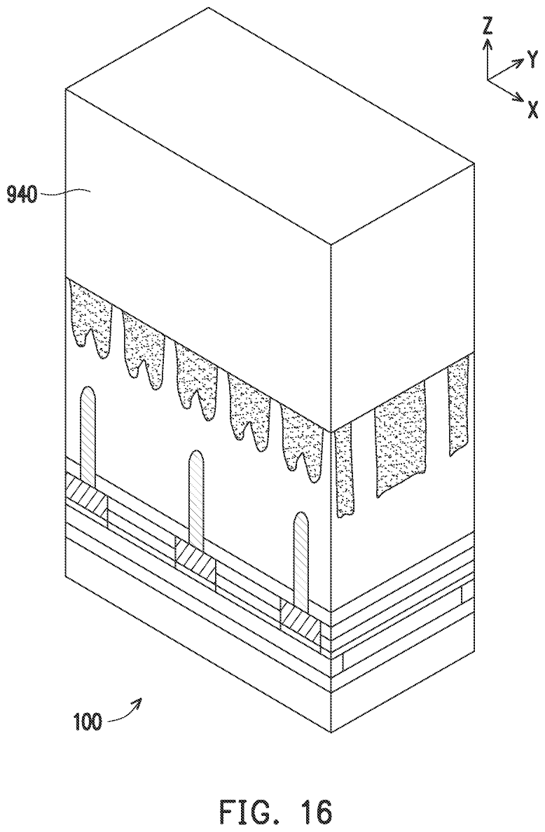

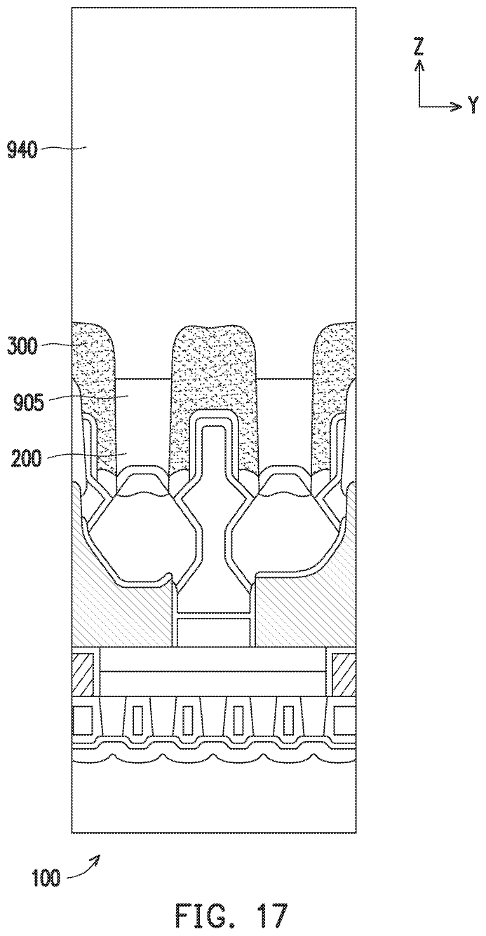

In FIG. 16, a dielectric material 940 is deposited over the partially fabricated semiconductor structure 100 of FIGS. 14-15. FIG. 17 is a cross-sectional view of FIG. 16. As shown, the dielectric material 940 contacts the mesa portions 905 of the fins 200 and the STI regions 300. As exemplary dielectric material 940 is silicon oxide.

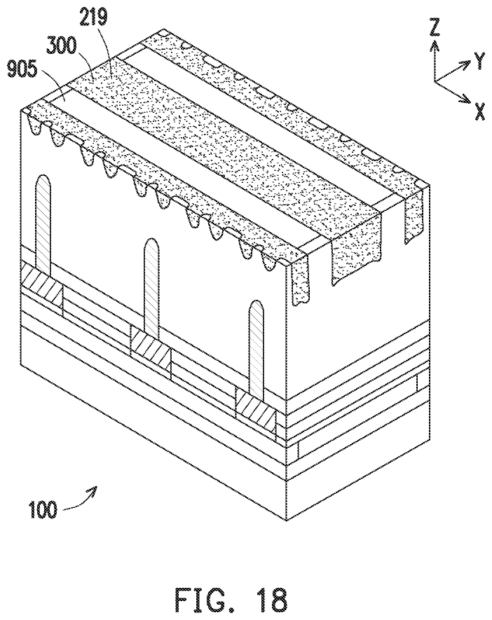

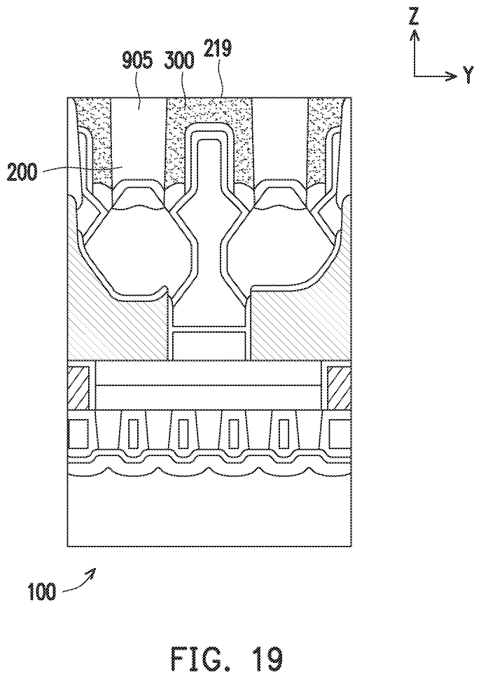

In FIG. 18, a chemical-mechanical planarization process is performed to remove the oxide dielectric material 940 and planarize the mesa portions 905 of the fins 200 and the STI regions 300 to a same backside 219. Thus, the backside 219 is planar. FIG. 19 is a cross-sectional view of FIG. 18.

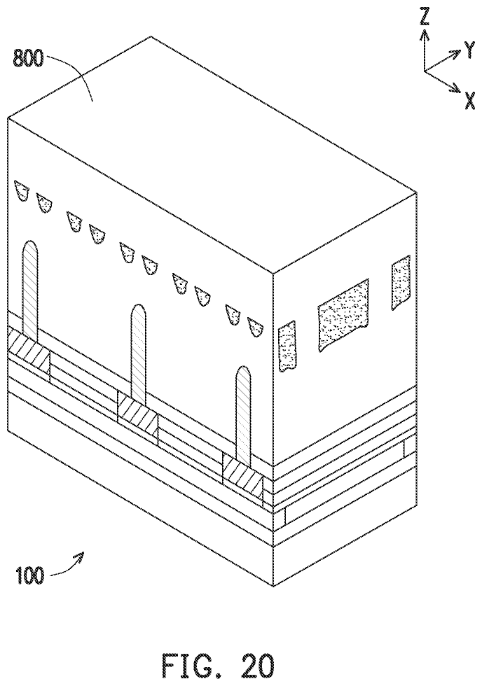

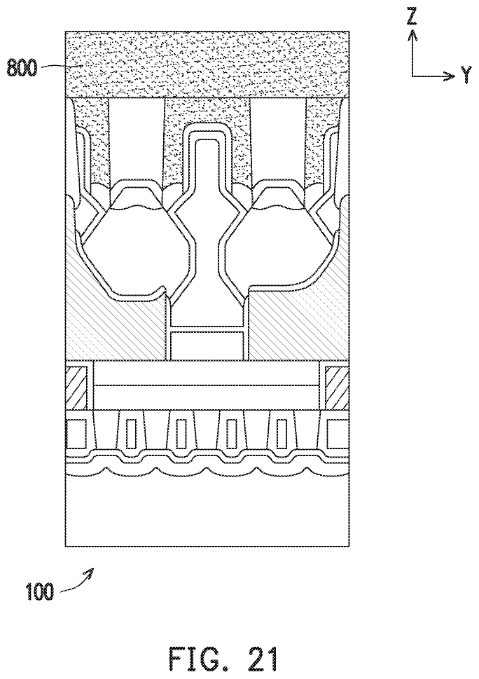

In FIG. 20, the method includes depositing a hard mask or inner isolation layer 800. An exemplary inner isolation layer 800 is silicon nitride. FIG. 21 is a cross-sectional view of FIG. 20.

The cross-sectional views of FIGS. 11, 13, 15, 17, 19, and 21 are Y-cuts, across two adjacent fins.

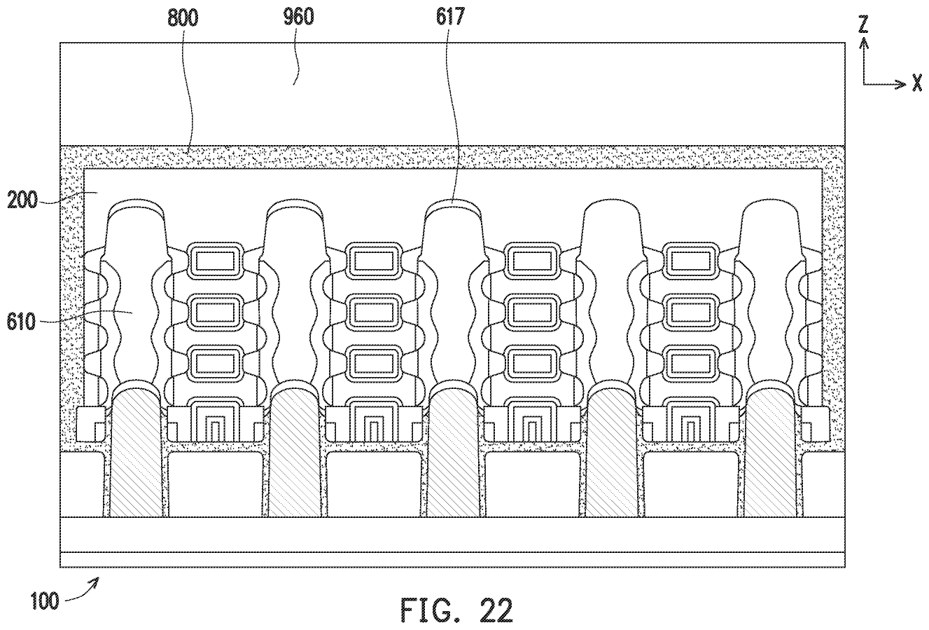

FIGS. 22-24 are X-cut cross-sectional views along a single fin illustrating the method at various stages of fabrication. In FIGS. 22-24, the epitaxial source/drain features 610 are illustrated as optionally including bottom structures 617 in the form of flexible bottom insulators (FBIs). Specifically, some source/drain features 610 include bottom structures 617 in the form of flexible bottom insulators (FBIs), and some source/drain features 610 do not include bottom structures 617. It is further contemplated that all source/drain features 610 may include bottom structures 617 in the form of flexible bottom insulators (FBIs) or that no source/drain features 610 include bottom structures 617.

In FIG. 22, a hard mask, such as a bi-layer hard mask 960 is formed over the inner isolation layer 800.

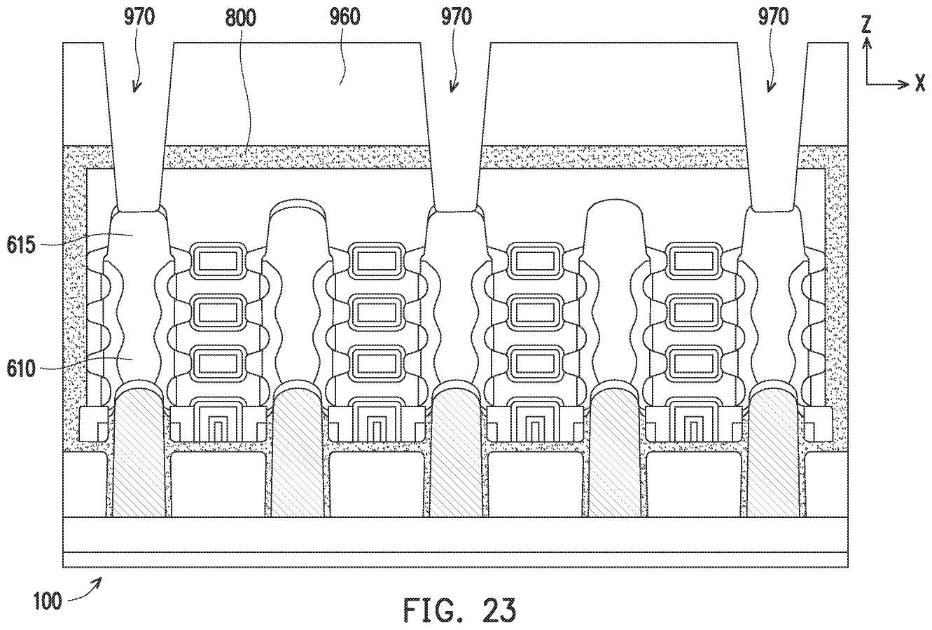

In FIG. 23, photolithography and etching processes are performed to etch trenches 970 that land on selected source/drain features 610. In certain embodiments, the trenches 970 land on highly doped material 615 in the source/drain features 610.

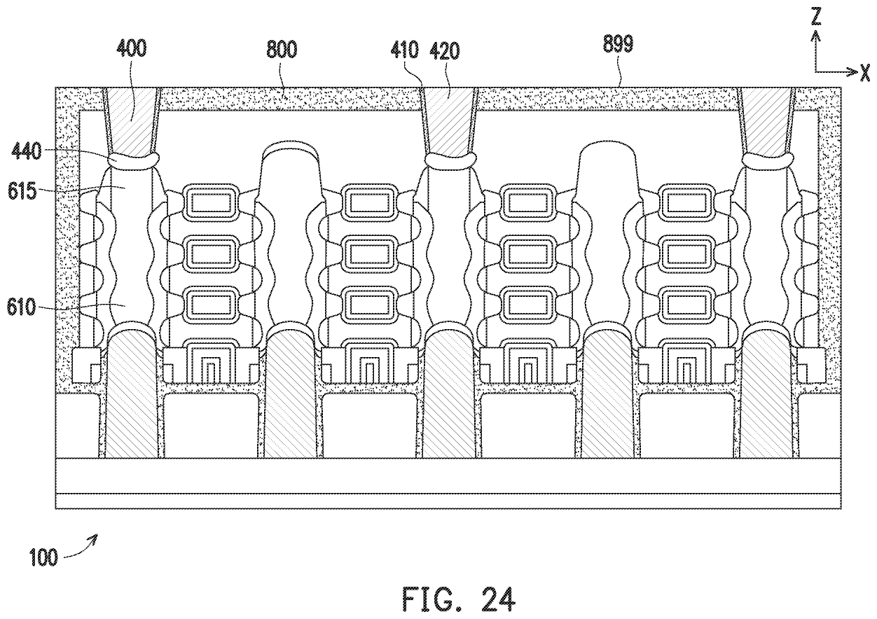

In FIG. 24, backside vias 400 are formed in the trenches 970. For example, a dielectric layer 420 may be formed along the trench sidewall. Further, silicide 440 may be formed on the source/drain feature in the trenches 970, and a plug material may be deposited in the trenches 970 to form the conductive core 410, followed by a planarization process to form the shared surface 899 defined by the isolation layer 800 and the backside vias 400.

As shown, the backside vias 400 are formed in contact with highly doped material 615, which reduces resistance as a result of the higher dopant concentration.

In the embodiment of FIGS. 22-24, the bottom structures 617 may not be utilized, and the via etch depth into the source/drain feature may be increased to enlarge the backside via—metal gate Z-direction space.

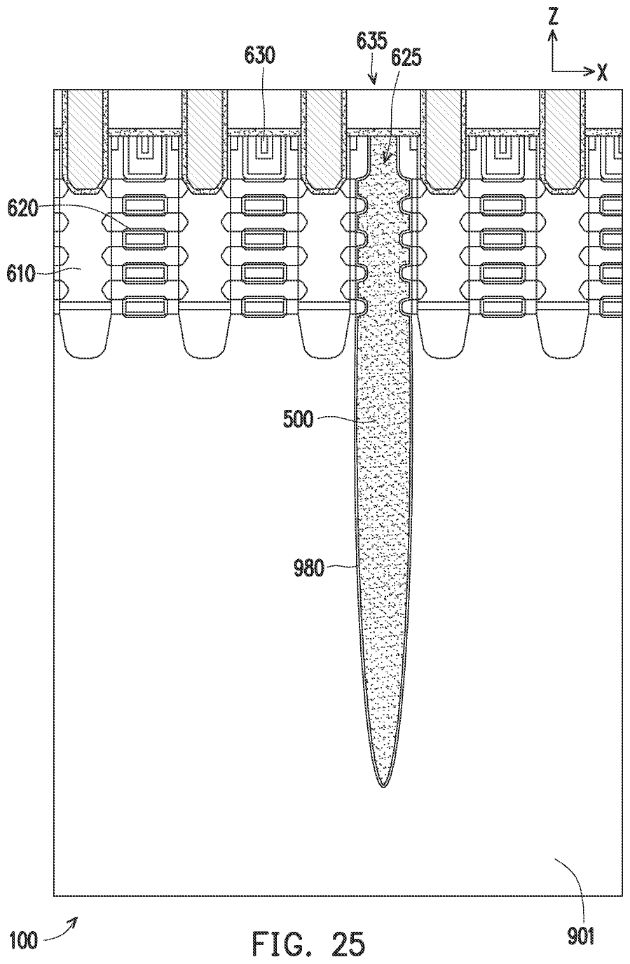

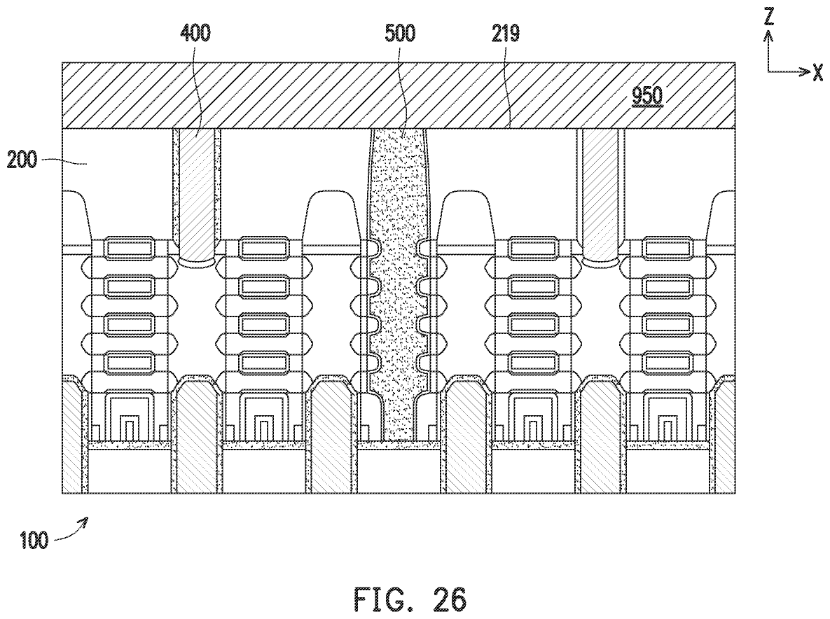

Referring now to FIGS. 25-26, an embodiment of a method for forming a semiconductor structure 100 with a CPODE isolation structure 500 is described.

As shown in FIG. 25, after forming source/drain features 610, active regions 620, and gates 630, a CPODE process is performed to remove a selected gate 635 and selected active region 625 underlying the gate to create a barrier between devices. For example, a CPODE process may include patterning a mask with an opening over a desired location of the CPODE structure 500, such as over a gate to be removed. An etch or series of etch processes is then performed and may land in the substrate 901. According to some embodiments, a wet etch, a dry etch, combinations, or the like may be used.

As shown, the etch process removes the selected gate 635, underlying active region 625 and forms a deep trench 980 into the semiconductor substrate 901.

After further front side processing, as described above, the semiconductor structure 100 is then flipped, as shown in FIG. 26, and the backside of the semiconductor substrate is thinned as described above. Then, a mask is patterned over the backside of the semiconductor structure 100, and trenches are etched to form backside vias 400 as described above. Thereafter, the mask may be removed and a backside interconnect structure 950 formed directly on the backside vias 400, the CPODE isolation structure, and the backside 219 of the remaining portions of the fins 200. In this manner, the semiconductor structure of FIG. 4 is fabricated.

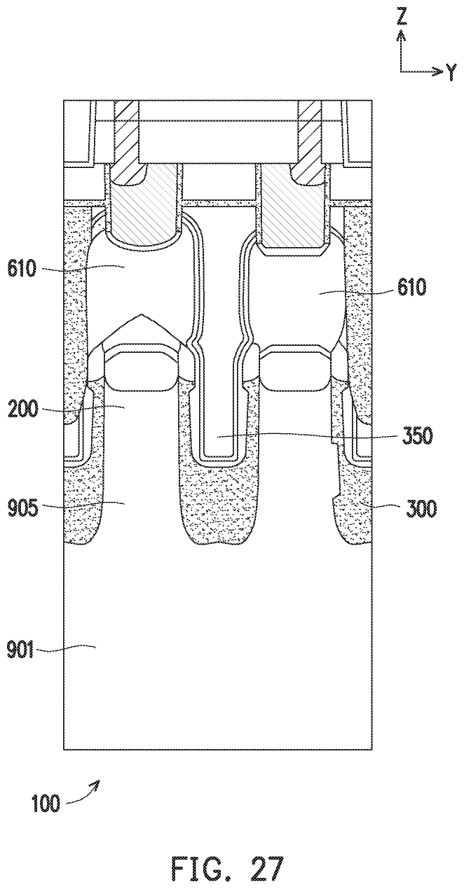

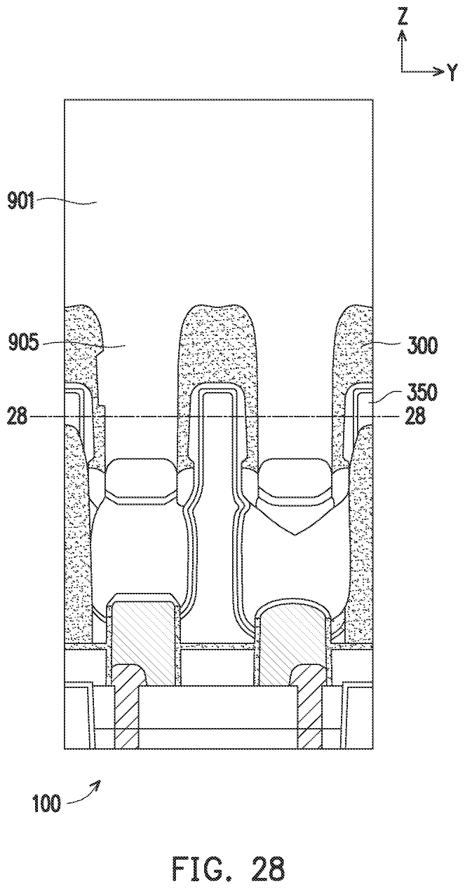

Referring now to FIGS. 27-28, an embodiment of a method for forming a semiconductor structure 100 with inter-fin isolation is further described.

As shown in FIG. 27, fins 200 are etched from a substrate 901 and shallow trench isolation regions 300 are formed between the fins. Further, ILD regions 350 may be formed over the STI regions 300 and between source/drain features 610.

After front side processing, the semiconductor structure 100 of FIG. 27 is flipped over as shown in FIG. 28. Then the backside thinning and/or removal process removes the portions of the semiconductor substrate 901, mesa portions 905, and STI regions 300 above line 28-28 to establish the semiconductor structure with the planar backside 219. Then, an inner isolation layer 800 is formed over the backside 219 of the semiconductor structure 100, as shown in FIG. 5.

As described herein, substrate isolation is provided by backside via structures in some embodiments. Further, in some embodiments, CPODE structures provide for substrate isolation as a result of substrate thin down, i.e., the thin down process removes a portion of the CPODE structure. In some embodiments, device areas are isolated from one another as a result of substrate thin down.

In an embodiment, a semiconductor structure includes a first fin extending in an X-direction and a second fin parallel to the first fin and distanced from the first fin in a Y-direction perpendicular to the X-direction. Each fin is formed with a first device area and a second device area aligned in the X-direction. The semiconductor structure includes an isolation region disposed between the first fin and the second fin; an isolation structure disposed between the first device area and the second device area in each fin; and an isolation layer disposed under the first fin and the second fin. The isolation region contacts the isolation layer, the isolation structure contacts the isolation layer, and the isolation region contacts the isolation structure to isolate the first fin from the second fin and to isolate the first device area from the second device area in each fin.

In certain embodiments of the semiconductor structure, each device area includes: a source feature and a drain feature over the respective fin; an active region between the source feature and the drain feature; and a gate structure over the active region.

In certain embodiments, the semiconductor structure further includes an active backside via in contact with the source feature in each device area; and a backside interconnect structure disposed under each fin and adjacent to the isolation layer. Each active backside via contacts the backside interconnect structure.

In certain embodiments, the semiconductor structure further includes a frontside interconnect structure disposed over the source feature, the drain feature, and the gate structure of each device area.

In another embodiment, a semiconductor structure includes a first device area and a second device area adjacent to the first device area. Each device area includes a semiconductor substrate; a source feature and a drain feature over the semiconductor substrate; an active region between the source feature and the drain feature; and a gate structure over the active region. The semiconductor structure further includes an isolation structure disposed between the semiconductor substrate in the first device area and the semiconductor substrate in the second device area. Each semiconductor substrate terminates at a backside, and the isolation structure extends to the backside.

In certain embodiments of the semiconductor structure, the isolation structure is a dummy backside via including a conductive core surrounded by a dielectric layer.

In certain embodiments, the semiconductor structure further includes an isolation layer disposed under the backside of each semiconductor substrate, wherein the isolation structure contacts the isolation layer.

In certain embodiments, the semiconductor structure further includes an active backside via in contact with the source feature in the first device area; a backside interconnect structure disposed under the backside of the semiconductor substrate in the first device area and adjacent to the isolation layer, wherein the active backside via contacts the backside interconnect structure.

In certain embodiments of the semiconductor structure, each device area includes a terminal active region; the semiconductor structure further includes a dummy feature disposed between the terminal active regions; and the isolation structure contacts the dummy feature.

In certain embodiments, the semiconductor structure further includes a frontside interconnect structure disposed over the source feature, the drain feature, and the gate structure of each device area.

In certain embodiments of the semiconductor structure, the isolation structure is formed by a continuous poly on diffusion edge (CPODE) process.

In certain embodiments of the semiconductor structure, each device area includes a terminal active region; and the isolation structure is disposed between the terminal active regions.

In another embodiment, a method includes etching a front side of a semiconductor substrate to form a first fin and a second fin parallel to the first fin, wherein an unetched portion of the semiconductor substrate adjacent to a backside of the semiconductor substrate connects the first fin and the second fin; forming an isolation region over the unetched portion of the semiconductor substrate between the first fin and the second fin; forming a first semiconductor device over the first fin and a second semiconductor device over the second fin; and removing the unetched portion of the semiconductor substrate connecting the first fin and the second fin to electrically isolate the first fin from the second fin.

In certain embodiments of the method, removing the unetched portion of the semiconductor substrate connecting the first fin and the second fin to electrically isolate the first fin from the second fin includes forming a recessed backside of the first fin and a recessed backside of the second fin, and wherein the method further includes forming an isolation layer on the recessed backside of the first fin and on the recessed backside of the second fin.

In certain embodiments of the method, the first semiconductor device includes P-doped epitaxial material; and the second semiconductor device includes N-doped epitaxial material.

In certain embodiments of the method, forming the first semiconductor device over the first fin includes forming a first device area and a second device area adjacent to the first device area, wherein each device area includes: a source feature and a drain feature over the first fin; an active region between the source feature and the drain feature; and a gate structure over the active region. Forming the first semiconductor device over the first fin further includes forming an isolation structure disposed in the first fin between the first device area and the second device area, wherein an underlying portion of the semiconductor substrate is disposed directly under the isolation structure. In embodiments, removing the unetched portion of the semiconductor substrate connecting the first fin and the second fin to electrically isolate the first fin from the second fin includes removing the underlying portion of the semiconductor substrate to electrically isolate the first device area from the second device area.

In certain embodiments of the method, the isolation structure is a dummy backside via including a conductive core surrounded by a dielectric layer.

In certain embodiments, the method further includes forming an isolation layer disposed under each fin, wherein the isolation structure contacts the isolation layer.

In certain embodiments of the method, the isolation structure is formed by a continuous poly on diffusion edge (CPODE) process.

In certain embodiments of the method, each device area includes a terminal source/drain region; and the isolation structure is disposed between the terminal source/drain regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first fin extending in an X-direction and a second fin parallel to the first fin and distanced from the first fin in a Y-direction perpendicular to the X-direction, wherein each fin is formed with a first device area and a second device area aligned in the X-direction;
an isolation region disposed between the first fin and the second fin;
an isolation structure disposed between the first device area and the second device area in each fin; and
an isolation layer disposed under the first fin and the second fin, wherein the isolation region contacts the isolation layer, the isolation structure contacts the isolation layer, and the isolation region contacts the isolation structure to isolate the first fin from the second fin and to isolate the first device area from the second device area in each fin.

2. The semiconductor structure of claim 1, wherein each device area comprises:
a source feature and a drain feature over the respective fin;
an active region between the source feature and the drain feature; and
a gate structure over the active region.

3. The semiconductor structure of claim 2, further comprising:
an active backside via in contact with the source feature in each device area; and
a backside interconnect structure disposed under each fin and adjacent to the isolation layer, wherein each active backside via contacts the backside interconnect structure.

4. The semiconductor structure of claim 3, further comprising:
a frontside interconnect structure disposed over the source feature, the drain feature, and the gate structure of each device area.

5. A semiconductor structure, comprising:
a first device area and a second device area adjacent to the first device area, wherein each device area comprises:
a semiconductor substrate;
a source feature and a drain feature over the semiconductor substrate;
an active region between the source feature and the drain feature; and
a gate structure over the active region;
an isolation structure disposed between the semiconductor substrate in the first device area and the semiconductor substrate in the second device area;
wherein each semiconductor substrate terminates at a backside, and wherein the isolation structure extends to the backside.

6. The semiconductor structure of claim 5, wherein the isolation structure is a dummy backside via comprising a conductive core surrounded by a dielectric layer.

7. The semiconductor structure of claim 6, further comprising:
an isolation layer disposed under the backside of each semiconductor substrate, wherein the isolation structure contacts the isolation layer.

8. The semiconductor structure of claim 7, further comprising:
an active backside via in contact with the source feature in the first device area; and
a backside interconnect structure disposed under the backside of the semiconductor substrate in the first device area and adjacent to the isolation layer, wherein the active backside via contacts the backside interconnect structure.

9. The semiconductor structure of claim 6, wherein:
each device area comprises a terminal active region;
the semiconductor structure further comprises a dummy feature disposed between the terminal active regions; and
the isolation structure contacts the dummy feature.

10. The semiconductor structure of claim 5, further comprising:
a frontside interconnect structure disposed over the source feature, the drain feature, and the gate structure of each device area.

11. The semiconductor structure of claim 5, wherein the isolation structure is formed by a continuous poly on diffusion edge (CPODE) process.

12. The semiconductor structure of claim 11, wherein:
each device area comprises a terminal source/drain region; and
the isolation structure is disposed between the terminal source/drain regions.

13. A method, comprising:
etching a front side of a semiconductor substrate to form a first fin and a second fin parallel to the first fin, wherein an unetched portion of the semiconductor substrate adjacent to a backside of the semiconductor substrate connects the first fin and the second fin;
forming an isolation region over the unetched portion of the semiconductor substrate between the first fin and the second fin;
forming a first semiconductor device over the first fin and a second semiconductor device over the second fin; and
removing the unetched portion of the semiconductor substrate connecting the first fin and the second fin to electrically isolate the first fin from the second fin.

14. The method of claim 13, wherein removing the unetched portion of the semiconductor substrate connecting the first fin and the second fin to electrically isolate the first fin from the second fin comprises forming a recessed backside of the first fin and a recessed backside of the second fin, and wherein the method further comprises forming an isolation layer on the recessed backside of the first fin and on the recessed backside of the second fin.

15. The method of claim 13, wherein:
the first semiconductor device comprises P-doped epitaxial material; and
the second semiconductor device comprises N-doped epitaxial material.

16. The method of claim 13, wherein forming the first semiconductor device over the first fin comprises:
forming a first device area and a second device area adjacent to the first device area, wherein each device area comprises:
a source feature and a drain feature over the first fin;
an active region between the source feature and the drain feature; and
a gate structure over the active region; and
forming an isolation structure disposed in the first fin between the first device area and the second device area, wherein an underlying portion of the semiconductor substrate is disposed directly under the isolation structure; and
wherein removing the unetched portion of the semiconductor substrate connecting the first fin and the second fin to electrically isolate the first fin from the second fin comprises removing the underlying portion of the semiconductor substrate to electrically isolate the first device area from the second device area.

17. The method of claim 16, wherein the isolation structure is a dummy backside via comprising a conductive core surrounded by a dielectric layer.

18. The method of claim 17, further comprising forming an isolation layer disposed under each fin, wherein the isolation structure contacts the isolation layer.

19. The method of claim 16, wherein the isolation structure is formed by a continuous poly on diffusion edge (CPODE) process.

20. The method of claim 19, wherein:
each device area comprises a terminal active region; and
the isolation structure is disposed between the terminal active regions.
